(19) United States
(12) Patent Application Publication
(10) Pub. No.: US 2007/0242422 A1
(43) Pub. Date: Oct. 18, 2007

(54) Host unit case with foldable lateral walls for a computer

(75) Inventors: Sheng-Hsiung Cheng, Taipei Hsien (TW); Te-An Lin, Taipei Hsien (TW); Wu-Nan Wang, Taipei Hsien (TW); Chia-Chia Huang, Taipei Hsien (TW)

Correspondence Address: BRUCE H. TROXELL, SUITE 1404, 5205 LEESBURG PIKE, FALLS CHURCH, VA, 22041, US

(73) Assignee: AOPEN INC., Taipei Hsien (TW)

(21) Appl. No.: 11/592,231

(22) Filed: Nov. 3, 2006

(30) Foreign Application Priority Data
Apr. 14, 2006 (TW) 095113262

(51) Int. Cl. H05K 5/02

(52) U.S. Cl. 361/683

(57) ABSTRACT

A host unit case with foldable lateral walls for a computer provides a lateral wall, which is composed of a first plate member and a second plate member and the plate members pivotally connect with each other. The first and second plate members are pivotally connected with a front wall and the first lateral edge of a rear wall. The lower end of the rear wall pivotally connects with the rear end of a lower cover. All parts are capable of being folded easily to reduce volume of the packaged host unit case. When the packaged host unit case is unfolded, the front and rear walls are joined to the upper and lower covers respectively such that the host unit case is set up completely conveniently and quickly.

### BACKGROUND OF THE INVENTION

1. Field of the Invention

The present invention is related to a host unit case of a personal computer and particularly to a built-up type host unit case of a computer.

2. Brief description of Related Art

The host unit case is employed to receive electronic devices such as a main board, hard disks, optical disk drives, floppy disk drives and power supply device. Usually, the host unit case is set up with an unchangeable structure. The composite type host unit case has prior art such as U.S. Pat. No. 6,961,236 and Taiwan Utility model publication No. M258544. U.S. Pat. No. 6,961,236 discloses a computer chassis and Taiwan Utility model publication No. M258544 discloses a host unit case to meet specifications of ATX and BTX.

Following prior art which is belonged to a further type for the host unit case is made available for being disassembled into several parts before being set up as the host unit case. Taiwan Patent Publication No. 468811 discloses a host unit case for an industrial computer. Taiwan Patent Publication No. 474423 discloses a computer chassis free from aid of hand tools. Taiwan Patent Publication No. 490120 discloses a composite type computer chassis. Taiwan Patent Publication No. 531142 discloses a composite type computer chassis assembly.

Further, the computer chassis free from aid of hand tools disclosed in Taiwan Patent Publication No. 474423 provides the front and rear cover plates, which are pivotally joined to a bottom plate with head pins, two frame plates for a big floppy disk drive, which are pivotally joined to the front and rear cover plates, and a cover plate for a small floppy disk drive is assembled to a frame plate and is fixedly hung to the bottom of frame plate for the big floppy disk drive. Further, four L shaped plates are fixed at four corners of the bottom plate to be joined to the two cover plates firmly. Finally, two lateral cover plates are hooked to the lateral sides of the preceding structure and fastened with set screws after the main board and the power supply frame being mounted to the preceding structure to complete the whole assembly of the computer chassis. The parts of the computer chassis are packaged separately such that less space is required for storage.

However, parts of the preceding prior art are so many and divided into several part groups and it is inconvenient to pick right parts during setting up the computer chassis such that it is hard to gather the parts before assembling and it takes a lot of time set up the computer chassis.

### SUMMARY OF THE INVENTION

The primary object is to provide a host unit case with foldable lateral walls for a computer with which the host unit case can be completely set up easily and quickly to enhance fun while the host unit case being set up by the user.

Another object is to provide a host unit case with foldable lateral walls for a computer with which the parts can be gathered together and reduced in a small volume while packaging for reducing delivery cost and saving storage space.

Accordingly, a host unit case with foldable lateral walls for a computer according to the present invention is capable of being reduced volume thereof while packaging and being completely set up conveniently and quickly and comprises:

a lateral wall, being composed of a first plate member and a second plate member and the plate members pivotally connecting with each other;

an upper cover;

a lower cover;

a front wall, having a first lateral edge to pivotally connect with the front end of the first plate member;

a rear wall, having a first lateral edge to pivotally connect with the rear end of the second plate member;

whereby, the preceding parts are capable of being extended to allow the front wall and the rear wall being joined to the upper and lower covers to allow the host unit case being completely set up conveniently and quickly for the host unit case being reduced the volume thereof while packaging.

### BRIEF DESCRIPTION OF THE DRAWINGS

The present invention can be more fully understood by reference to the following description and accompanying drawings, in which:

FIG. 1 is a perspective view of the first embodiment of a host unit case with foldable lateral walls for a computer according to the present invention;

FIG. 2 is a perspective view of the first embodiment of the host unit case shown in FIG. 1 illustrating the upper cover being detached;

FIG. 3 is a perspective view illustrating the lower cover of the host unit case of the invention being moved to the take-up position;

FIG. 4 is a perspective view illustrating the first and second support members being moved to the take-up position;

FIG. 5 is a perspective view illustrating the front and rear walls being moved to be close to each other;

FIGS. 6A, 6B and 6C side elevational views illustrating steps to unfold the host unit case of the first embodiment for separating the front, rear and lateral walls apart;

FIG. 7 is a perspective view of the second embodiment of the host unit case according to the present invention; and

FIGS. 8A, 8B, 8C and 8D are plan views illustrating steps for folding another embodiment of the first support member.

### DETAILED DESCRIPTION OF THE INVENTION

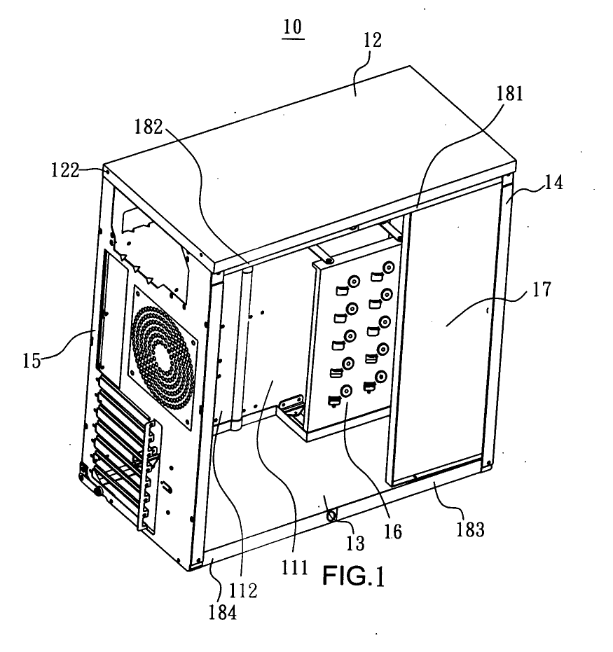

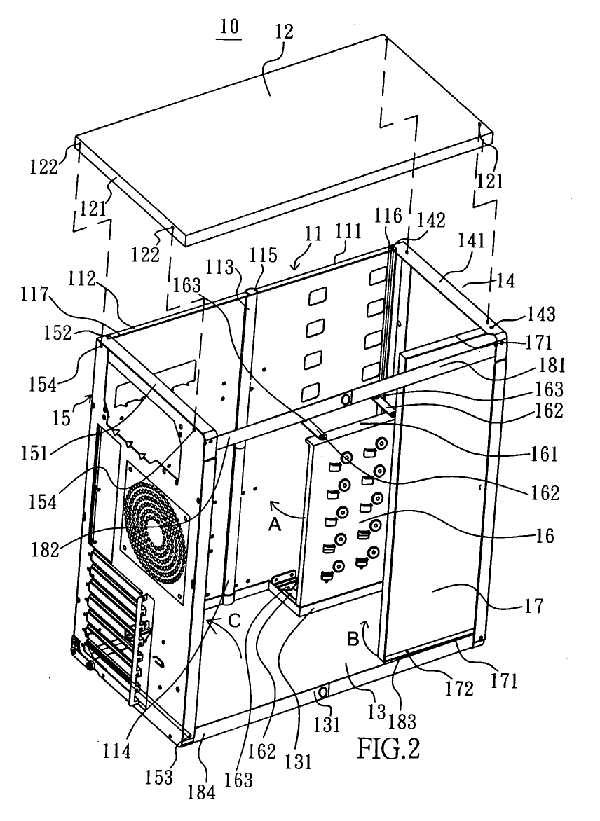

Referring to FIGS. 1 and 2, the first embodiment of a host unit case with foldable lateral walls according to the present invention is capable of being reduced volume thereof for packaging and being completely set up conveniently and quickly. The host unit case 10 includes a lateral wall 11, an upper cover 12, a lower cover 13, a front wall 14 and a rear wall 15. The lateral wall 11 is composed of a first plate member 111 and a second plate member 112, which pivotally connect with each other in a way of a fitting part 113, 114 being alternately disposed at the joining sides of the first plate member 111 and second plate member 112 and a pivot rod 115 passing through pivotal holes of the fitting parts 113, 114. Alternatively, a conventional pivotal device such as a hinge can be employed to have two pivotal parts thereof being joined to the first plate member 111 and the second plate member 112 respectively. The first and second plate members 111, 112 each provide a margin frame 116, 117 bending inward respectively. The upper cover 12 has a margin frame 121 extending downward with the margin frame 121 having fixing holes 122 at the sides of the front and rear ends of the upper cover 12. The lower cover 13 has a margin frame 131 extending upward. The front wall 14 has a margin frame 141 extending rearward. The margin frame 141 at the upper and lower ends of the first lateral edge of the front wall 14 presses the upper and lower ends of the margin frame 116. The margin frames 141, 116 have pivotal holes corresponding to each other such that the front end of the first plate member 111 and the first lateral edge of the front wall 14 pivotally connect with each other with pivotal shafts 142 passing through the corresponding pivotal holes. The rear wall 15 has a margin frame 151 extending forward. The margin frame 151 at the upper and lower ends of the first lateral edge of the rear wall 15 presses the upper and lower ends of the margin frame 117. The margin frames 151, 117 have pivotal holes corresponding to each other such that the second plate member 112 and the first lateral edge of the rear wall 15 pivotally connect with each other with pivotal shafts 152 passing through the corresponding pivotal holes. The margin frame 151 at the lower end of the rear wall 15 presses the margin frame 131 of the lower cover 13 and the margin frames 151, 131 have pivotal holes corresponding to each other such that the lower cover 13 and the rear wall 15 pivotally connect with each other with pivotal shafts 153 passing through the corresponding pivotal holes. The front wall 14 and the rear wall 15 have fixing holes 154 corresponding to fixing holes 122 at the upper cover 12 such that the front wall 14 and the rear wall 15 are joined to the upper cover 12 with screws passing through the corresponding holes 122, 154.

The first embodiment further includes a first support member 16 and a second support member 17. The first support member 16 has a horizontal bent shaped plate element 161 at the top and bottom thereof and the front and rear ends of the two horizontal bent shaped plate element 161 are pivotally connected with an end of a connecting rod 162 respectively. The respective connecting rod 162 pivotally connects with a lug 163 at another end thereof and the lug 163 is joined to the first plate member 111. The margin frame 131 of the lower cover 13 presses the first support member 16 to fix the lower end of the first support member 16. The second support member 17 has a horizontal bent shaped plate element 171 at the top and bottom thereof. The margin frame 141 of the front wall 14 at the upper and lower ends of the second lateral edge thereof presses the plate elements 171. The margin frame 141 and the plate elements 171 provide fixing holes corresponding to each other such that the second support member 17 pivotally connects with the front wall 14 with pivotal shafts 143 passing through the pivotal holes. The plate element 171 at the bottom of the second support member 17 and the lower cover 13 have fixing holes 172 corresponding to each other such that the bottom of the second support member 17 can be joined to the lower cover 13 with screws passing through the corresponding fixing holes 172. The space between the first plate member 111 and the second support member 17 is larger enough to accommodate a first electronic device such as 5.25″ floppy disk drive. The space between the first support member 16 and the second support member 17 is smaller enough to accommodate the second electronic device such as 3.25″ floppy drive. The preceding pivotal structure between the first support member 16 and the first plate member 111 applies principle of four-connecting-rod linkage facilitates the first support member 16 to move along arrow A shown in FIG. 2 for being foldable to approach the first plate member 111. The four connecting rods 162 are capable of being arranged with either equal lengths or unequal lengths.

The first embodiment of present invention further includes a first long plate element 181, a second long plate element 182, a third long plate element 183 and a fourth long plate element 184. The front and rear ends of the first long plate element 181 pivotally connect with the upper end of the front wall 14 and the second long plate member 182. The rear end of the second long plate element 182 pivotally connects with the upper end of the rear wall 15. The front and rear ends of the third long plate element 183 pivotally connect with the lower end of the front wall 14 and the fourth long plate element 184. The rear end of the fourth long plate element 184 is pivotally connected to the lower end of the rear wall 15. The front wall 14 and the upper and lower ends of the second lateral edge at rear wall 15 are joined to the first, second, third and fourth long plate elements 181, 182, 183, 184 respectively to strengthen the unfolded host unit case 10.

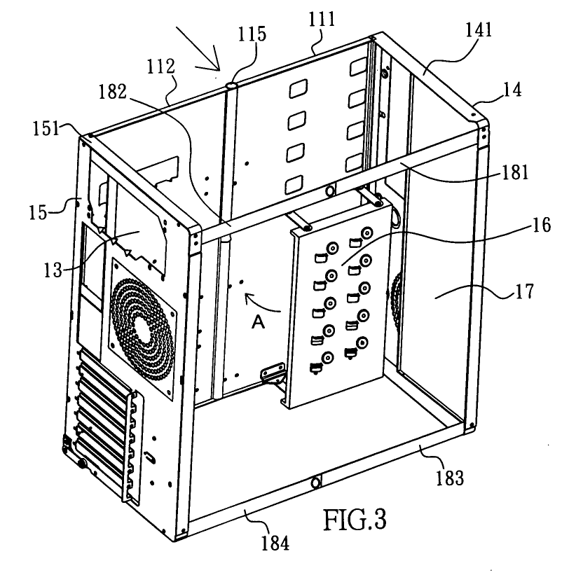

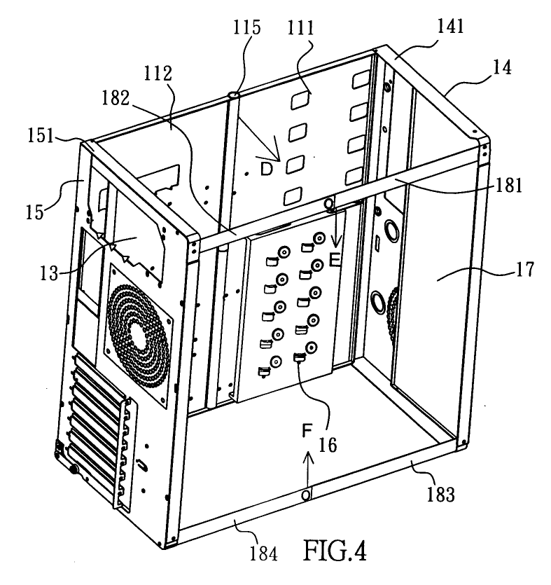

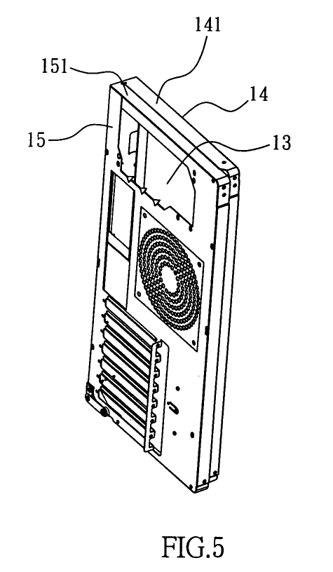

Referring to FIGS. 2, 3, 4 and 5, when the host unit case 10 of the first embodiment is folded, the upper cover 12 is detached from the front wall 14 and rear wall 15 first. Next, the second support member 17 is moved along arrow B shown in FIG. 2 to press the front wall 14. Then, the lower cover 13 close to an end of the front wall 14 is moved along arrow C shown in FIG. 2 to press the rear wall 15 as shown in FIG. 3. Further, the first support member 16 is moved along arrow A shown in FIG. 3 to press the first plate member 111 as shown in FIG. 4. Further, the pivotally joining parts between the first plate member 111 and the second plate member 112 are moved along arrow D shown in FIG. 4 and the pivotally joining parts between first and second long 181, 182 plate elements are moved and along arrow E shown in FIG. 5. In this way, the pivotally joining parts between third and fourth long 183, 184 plate elements are moved along arrow F shown in FIG. 4 to allow the first plate member 111 and the first and third long plate elements 181, 183 press the front wall 14 and allow the second plate member 112 and the second and fourth long plate elements 182, 184 press the rear wall 15 respectively. In this way, the margin frames 141, 151 of the front and rear walls 14, 15 press to each other as shown in FIG. 5 to form a folded state such that a great deal of space occupied by the host unit case 10 is reduced significantly.

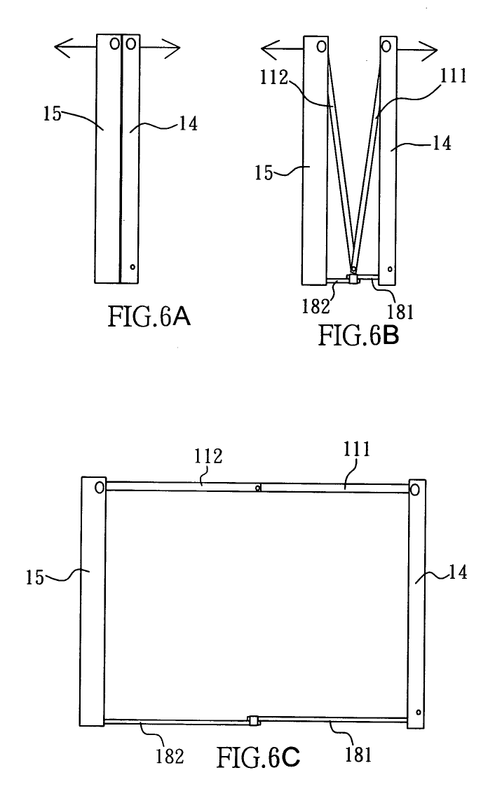

Referring to FIGS. 2, 6A, 6B and 6C, when the host unit case of the present embodiment is unfolded, the front wall 14 and the rear wall 15 are moved forward and rearward first to move the pivotal parts between the first and second long plate elements 181, 182 upward and the pivotal parts between the third and fourth long plate elements 183, 184 downward as shown in FIG. 6A to extend the pivotal parts gradually as shown in FIG. 6B till being fully unfolded as shown in FIG. 6C. Referring to FIG. 2, the second support member 17 is lifted after the first support member 16 and the lower cover 13 being lifted and the first and the second support members 16, 17 are joined to the lower cover 13. In this way, the upper cover 12 is capable of being joined to the front wall 14 and the rear wall 15 to form a complete host unit case 10 conveniently and quickly.

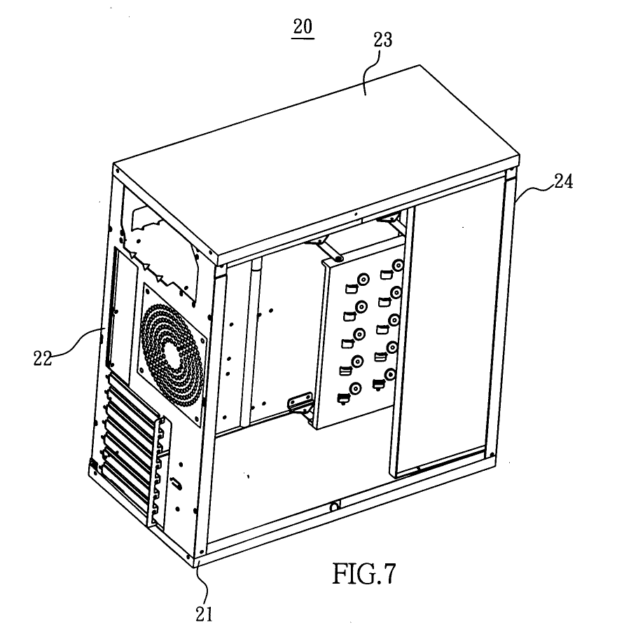

Referring to FIG. 7, the second embodiment of the host unit case with foldable lateral walls for a computer according to the present invention is illustrated. The host unit case 20 of the present embodiment is almost the same as the first embodiment and the only difference of the present embodiment from the previous embodiment is in that the lower cover 21, the front wall 24 and the rear wall 22 have fixing holes corresponding to each other such that the front wall 24 and the rear wall 22 are joined to the lower cover 21 respectively with screws passing through the corresponding fixing holes instead of the lower cover 21 pivotally connecting with the rear wall 22.

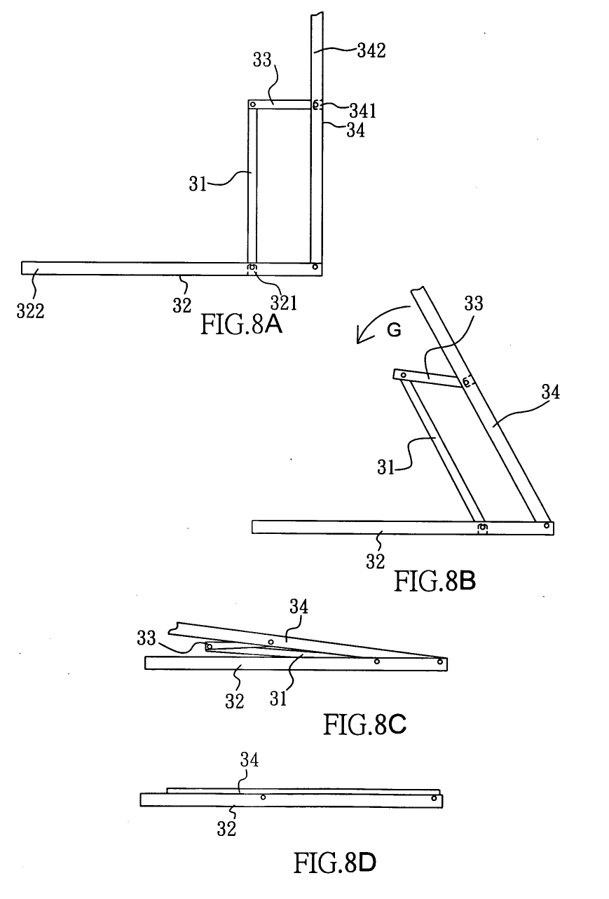

Referring to FIGS. 8A, 8B, 8C and 8D, another embodiment of the first support member 31 is illustrated. The front end of the first support member 31 pivotally connects with the lug 321 at the front wall 32 and the rear end of the first support member 31 is pivotally connected to the connecting rod 33. Another end of the connecting rod 33 is pivotally joined to the lug 341 of the first plate element 34 on the lateral wall. The margin frame 322 of the front wall 32 is pivotally connected to the margin frame 342 of the first plate member 34 of the lateral wall as shown in FIG. 8A. The first support member 31 is movable with the front wall 32 and the first plate member 34 of the lateral wall such that the first plate member 34 of the lateral wall moves along arrow G shown in FIG. 8B to be close to the front wall 32 to allow the first support member 31 approaching between the front wall 32 and the first plate member 34 of the lateral wall. Steps of folding shown in FIGS. 8B, 8C and 8D facilitate the first support member 31 to be operated conveniently.

It is appreciated that the host unit case with foldable lateral walls for a computer according to the present invention is capable of being set up a complete host unit case easily and quickly to enhance fun with self setting up the host unit case and be favorable for decreasing delivery cost and saving available storage space.

While the invention has been described with referencing to preferred embodiments thereof, it is to be understood that modifications or variations may be easily made without departing from the spirit of this invention, which is defined by the appended claims.

What is claimed is:

1. A host unit case with foldable lateral walls for a computer, which is capable of being reduced volume thereof while packaging and being completely set up conveniently and quickly, comprising:
A lateral wall, being composed of a first plate member and a second plate member and the plate members pivotally connecting with each other;
an upper cover;
a lower cover;
a front wall, having a first lateral edge to pivotally connect with the front end of the first plate member;
a rear wall, having a first lateral edge to pivotally connect with the rear end of the second plate member;
whereby, the preceding parts are capable of being extended to allow the front wall and the rear wall being joined to the upper and lower covers such that the host unit case is set up completely.

2. The host unit case with foldable lateral walls for a computer as defined in claim 1, wherein the first plate member and the second plate member each have a bent shaped first margin frame extending inward respectively; the front wall has a second margin frame extending rearward; and the second margin frame at the upper and lower ends of a first lateral edge, which is provided at the front wall, and the first margin frame at the front end of the first plate member have pivotal holes corresponding to each other such that the front end of the first plate member and the front wall pivotally connect with each other with pivotal shafts passing through the corresponding pivotal holes.

3. The host unit case with foldable lateral walls for a computer as defined in claim 2, wherein the rear wall has a third margin frame extending forward and the third margin frame at the upper and lower ends of another first lateral edge, which is provided at the rear wall, and the first margin frame at the upper and lower end of the rear end of the second plate member have pivotal holes corresponding to each other such that the rear end of the second plate member pivotally connects with the rear wall with pivotal shafts passing through the pivotal holes.

4. The host unit case with foldable lateral walls for a computer as defined in claim 3 further comprises a first long plate element and a second long plate element with the front and rear ends of the first long plate element pivotally connecting with the upper end of the front wall and the front end of the second long plate element; and the rear ends of the second long plate element pivotally connecting with the upper end of the rear wall.

5. The host unit case with foldable lateral walls for a computer as defined in claim 4 further comprises a third long plate element and a fourth long plate element with the front and rear ends of the third long plate element pivotally connecting with the lower end of the front wall and the front end the fourth long plate element; and the rear end of the fourth plate member pivotally connects with the lower end of the rear wall.

6. The host unit case with foldable lateral walls for a computer as defined in claim 3, wherein the lower cover has a fourth margin frame extending upward; the third margin frame at the lower end of the rear wall and the fourth margin frame have pivotal holes corresponding to each other such that the lower cover pivotally connects with the rear wall with pivotal shafts passing through the pivotal holes.

7. The host unit case with foldable lateral walls for a computer as defined in claim 4, wherein the lower cover has a fourth margin frame extending upward; the third margin frame at the lower end of the rear wall and the fourth margin frame have pivotal holes corresponding to each other such that the lower cover pivotally connects with the rear wall with pivotal shafts passing through the pivotal holes.

8. The host unit case with foldable lateral walls for a computer as defined in claim 3, wherein the front wall and the rear wall provide fixing holes corresponding to fixing holes at the lower cover such that the front wall and the rear wall are joined to the lower cover with screws passing through the corresponding fixing holes.

9. The host unit case with foldable lateral walls for a computer as defined in claim 4, wherein the front wall and the rear wall provide fixing holes corresponding to fixing holes at the lower cover such that the front wall and the rear wall are joined to the lower cover with screws passing through the corresponding fixing holes.

10. The host unit case with foldable lateral walls for a computer as defined in claim 3, wherein the front wall and the rear wall provide fixing holes corresponding to fixing holes at the upper cover such that the front wall and the rear wall are joined to the upper cover with screws passing through the corresponding fixing holes.

11. The host unit case with foldable lateral walls for a computer as defined in claim 4, wherein the front wall and the rear wall provide fixing holes corresponding to fixing holes at the upper cover such that the front wall and the rear wall are joined to the upper cover with screws passing through the corresponding fixing holes.

12. The host unit case with foldable lateral walls for a computer as defined in one of claims 1, wherein the first plate member further pivotally connects with a first support member.

13. The host unit case with foldable lateral walls for a computer as defined in claim 12, wherein the upper and lower ends of the first support member has a horizontally bent shaped plate body respectively with the front and rear end of the respective plate body being pivotally connected to an end of a connecting rod and another end of the connecting rod pivotally joined to a lug for being joined to the first plate member.

14. The host unit case with foldable lateral walls for a computer as defined in claim 13, wherein the fourth margin frame at the lower cover presses the lower end of the first support member.

15. The host unit case with foldable lateral walls for a computer as defined in claim 12, wherein a second lateral edge provided at the front wall pivotally connects with a second support member such that a first electronic device is joined between the first plate member and the second support member and a second electronic device is joined between the first and second support members.

16. The host unit case with foldable lateral walls for a computer as defined in claim 15, wherein the top and bottom of the second support member provide a horizontally bent shaped plate body respectively; the upper and lower ends of the front wall and the respective plate body have pivotal holes corresponding to each that such that the second support member pivotally connects with the front wall with pivotal shafts passing through the corresponding pivotal holes.

17. The host unit case with foldable lateral walls for a computer as defined in claim 15, wherein a fifth margin frame at the bottom of the second support member and the lower cover have fixing holes corresponding to each other such that the bottom of the second support member is joined to the lower cover with screws passing through the corresponding fixing holes.

18. The host unit case with foldable lateral walls for a computer as defined in any of claims 1 further comprises a first support member; the front end of the first support member pivotally connects with a lug and the lug is joined to the front wall; the rear end of the first support member pivotally connects with a connecting rod; another end of the connecting rod pivotally connects with another lug, which is joined to the first plate member of the lateral wall such that the first plate member is capable of being moved to be close to the front wall with the first support member being moved to be close to the front wall.

19. The host unit case with foldable lateral walls for a computer as defined in claim 18, wherein a second lateral edge provided at the front wall pivotally connects with a second support member such that a first electronic device is joined between the first plate member and the second support member and a second electronic device is joined between the first and second support members.

20. The host unit case with foldable lateral walls for a computer as defined in claim 19, wherein the top and bottom of the second support member provide a horizontally bent shaped plate body respectively; the upper and lower ends of the front wall and the respective plate body have pivotal holes corresponding to each that such that the second support member pivotally connects with the front wall with pivotal shafts passing through the corresponding pivotal holes.
